(19) United States
(12) Patent Application Publication
(10) Pub. No.: US 2017/0115326 A1
(43) Pub. Date: Apr. 27, 2017

(54) PROBE MODULE

(71) Applicant: MPI CORPORATION, ZHUBEI CITY (TW)

(72) Inventors: WEI-CHENG KU, ZHUBEI CITY (TW); CHIH-HAO HO, ZHUBEI CITY (TW); HAO WEI, ZHUBEI CITY (TW)

(73) Assignee: MPI CORPORATION, ZHUBEI CITY (TW)

(21) Appl. No.: 15/333,400

(22) Filed: Oct. 25, 2016

(30) Foreign Application Priority Data
Oct. 27, 2015 (TW) 104135300

(51) Int. Cl. G01R 1/067; G01R 1/073

(52) U.S. Cl. CPC G01R 1/06794; G01R 1/07342

(57) ABSTRACT

A probe module includes a base adapted to be fixed to a tester, an engaging seat engaged with the base, a signal connector, an electrical signal transmitting member, and two probes located below the engaging seat. The engaging seat has an engaging opening and a first end surface. The signal connector is provided in the engaging opening, and has a signal conductive portion and a conductive ground. A signal wire and a ground layer of the electrical signal transmitting member are electrically connected to the signal conductive portion and the conductive ground, respectively. The probes are electrically connected to the signal wire and the ground layer, respectively. The probes extend out of a first extending reference plane of the first end surface. Alternatively, a reflector is used to reflect an image of the probes upward. Whereby, a length of the electrical signal transmitting member can be further shortened.

### BACKGROUND OF THE INVENTION

1. Technical Field

The present invention relates generally to testing electronic components, and more particularly to a probe module.

2. Description of Related Art

To test if every electronic component of a device-under-test (DUT) is electrically connected correctly, a widely used method is to apply a probe module between a tester and the DUT to transmit test signals to the DUT.

A conventional probe module 1 is illustrated in FIG. 1 and FIG. 2, which includes a base 10, an engaging seat 12, a signal connector 14, an electrical signal transmitting member 16, and a plurality of probes 18. The base 10 is adapted to be fixed to a tester (not shown). The engaging seat 12 is engaged with the base 10, and tilts downward. The engaging seat 12 has a front end surface 122 and a front end angle 124, wherein the front end surface 122 faces a DUT, and an included angle is formed between an extending reference plane 122a of the front end surface 122 and a tested surface A01 of the DUT A; the front end angle 124 is located on a side which is away from the base 10. The signal connector 14 is provided on the engaging seat 12. The electrical signal transmitting member 16 is disposed in the engaging seat 12, wherein the electrical signal transmitting member 16 is electrically connected to the signal connector 14 with an end thereof, while another end thereof extends out of the front end surface 122 to be electrically connected to the probes 18. Whereby, the locations of the probes 18 could be seen from above the probe module 1 with naked eyes or a microscope, which facilitates the process of making the probes 18 contact with a tested portion of the DUT A.

While testing with high-frequency signals, the small amount of inductance attached on the probe module 1 is directly proportional to the length of the signal transmission path. In other words, the longer the signal transmission path is, the higher the reactance generated by the high-frequency signals would be, leading to a potential signal loss.

To shorten the signal transmission path, the most instinct way is to shorten the length of the electrical signal transmitting member 16. However, even if the length of the electrical signal transmitting member 16 is shortened, the locations of the probes 18 still have to be observed from above the probe module 1. Due to such structural limitation, part of the electrical signal transmitting member 16 of the probe module 1 would be shaded by the front end angle 124. In light of this, the length of the electrical signal transmitting member 16 could not be easily further shortened.

### BRIEF SUMMARY OF THE INVENTION

In view of the above, the primary objective of the present invention is to provide a probe module, which could provide a shorter signal transmission path.

The present invention provides a probe module, which is provided between a tester and a device-under-test (DUT) to abut against a tested surface of the DUT. The probe module includes a base, an engaging seat, a signal connector, an electrical signal transmitting member, and at least two probes. The base is adapted to be fixed to the tester. The engaging seat is engaged with the base, wherein the engaging seat has an engaging opening and a first end surface. The engaging opening goes through the engaging seat. A defined first extending reference plane of the first end surface is perpendicular to the tested surface of the DUT. The signal connector is provided at the engaging seat and in the engaging opening, wherein the signal connector is adapted to be electrically connected to the tester. The signal connector has a signal conductive portion and a conductive ground. The electrical signal transmitting member is rod-shaped, and includes a signal wire made of a conducting material, an insulating layer made of an insulating material, and a ground layer made of a conducting material, wherein the insulating layer covers the signal wire, and the ground layer covers the insulating layer. The signal wire is electrically connected to the signal conductive portion, and the ground layer is electrically connected to the conductive ground. The at least two probes are made of a conducting material, and are adapted to abut against the tested surface of the DUT, wherein the at least two probes are electrically connected to the signal wire and the ground layer at an end of the electrical signal transmitting member, respectively. At least a part of each of the at least two probes extends out of the first extending reference plane from directly below the engaging seat.

The present invention further provides a probe module, which is provided between a tester and a device-under-test (DUT) to abut against a tested surface of the DUT. The probe module includes a base, an engaging seat, a signal connector, an electrical signal transmitting member, at least two probes, and a reflector. The base is adapted to be fixed to the tester. The engaging seat is engaged with the base, wherein the engaging seat has an engaging opening going through the engaging seat. The signal connector is provided at the engaging seat and in the engaging opening, wherein the signal connector is adapted to be electrically connected to the tester. The signal connector has a signal conductive portion and a conductive ground. The electrical signal transmitting member is rod-shaped, and is located within an orthogonal projection of the engaging seat, wherein the electrical signal transmitting member comprises a signal wire made of a conducting material, an insulating layer made of an insulating material, and a ground layer made of a conducting material, wherein the insulating layer covers the signal wire, and the ground layer covers the insulating layer. The signal wire is electrically connected to the signal conductive portion, and the ground layer is electrically connected to the conductive ground. The at least two probes are made of a conducting material, and are adapted to abut against the tested surface of the DUT, wherein the at least two probes are electrically connected to the signal wire and the ground layer at an end of the electrical signal transmitting member, respectively. The at least two probes are located below the engaging seat, and are within the orthogonal projection of the engaging seat. The reflector is provided on a side of the engaging seat, wherein the reflector has a reflective surface which is provided in a tilted manner, and corresponds to the at least two probes. The reflective surface is adapted to reflect an image of the at least two probes upward.

The present invention further provides a probe module, which is provided between a tester and a device-under-test (DUT) to abut against a tested surface of the DUT. The probe module includes a base, an engaging seat, a signal connector, an electrical signal transmitting member, and at least two probes. The base is adapted to be fixed to the tester. The engaging seat is engaged with the base, wherein the engaging seat has an engaging opening and a first end surface. The engaging opening goes through the engaging seat. The first end surface tilts toward the base from bottom to top. The signal connector is provided at the engaging seat and in the engaging opening, wherein the signal connector is adapted to be electrically connected to the tester. The signal connector has a signal conductive portion and a conductive ground. The conductive ground has an end edge, which aligns with a bottom edge of the first end surface. The electrical signal transmitting member is rod-shaped, and includes a signal wire made of a conducting material, an insulating layer made of an insulating material, and a ground layer made of a conducting material, wherein the insulating layer covers the signal wire, and the ground layer covers the insulating layer. The signal wire is electrically connected to the signal conductive portion, and the ground layer is electrically connected to the conductive ground. The at least two probes are made of a conducting material. The at least two probes are connected to the electrical signal transmitting member, and are adapted to abut against the tested surface of the DUT, wherein the at least two probes are electrically connected to the signal wire and the ground layer at an end of the electrical signal transmitting member, respectively. At least a part of each of the at least two probes extends out of an orthogonal projection of the engaging seat from directly below the engaging seat.

The present invention further provides a probe module, which is provided between a tester and a device-under-test (DUT) to abut against a tested surface of the DUT. The probe module includes a base, an engaging seat, a signal connector, an electrical signal transmitting member, and at least two probes. The base is adapted to be fixed to the tester. The engaging seat is engaged with the base, wherein the engaging seat has a first end surface, which has a notch formed thereon. The signal connector is adapted to be electrically connected to the tester. The signal connector has a signal conductive portion and a conductive ground, which is provided at the engaging seat and in the notch. The electrical signal transmitting member is rod-shaped, and includes a signal wire made of a conducting material, an insulating layer made of an insulating material, and a ground layer made of a conducting material, wherein the insulating layer covers the signal wire, and the ground layer covers the insulating layer. The signal wire is electrically connected to the signal conductive portion, and the ground layer is electrically connected to the conductive ground. The at least two probes are made of a conducting material. The at least two probes are connected to the electrical signal transmitting member, and are adapted to abut against the tested surface of the DUT, wherein the at least two probes are electrically connected to the signal wire and the ground layer at an end of the electrical signal transmitting member, respectively. At least a part of each of the at least two probes extends out of an orthogonal projection of the engaging seat from directly below the engaging seat.

Since the first end surface of the engaging seat is perpendicular to the tested surface of the DUT, a length of the electrical signal transmitting member could be shortened as much as possible, whereby a length of the signal transmission path would be shortened as well. In comparison, the electrical signal transmitting member of a conventional probe module is shaded by the front end angle of the engaging seat, and therefore a length of the electrical signal transmitting member is unavoidable long, as mentioned above. Such drawback could be overcome with the design disclosed in the present invention. In addition, by providing the reflector next to the engaging seat to reflect an image of the probes, by arranging the first end surface of the engaging seat in a tilted manner which leans toward the base from bottom to top, and by placing the engaging seat in the notch, the aforementioned drawback could be also avoided, which further shortens the length of the electrical signal transmitting member.

### BRIEF DESCRIPTION OF THE SEVERAL VIEWS OF THE DRAWINGS

The present invention will be best understood by referring to the following detailed description of some illustrative embodiments in conjunction with the accompanying drawings, in which

FIG. 1 is a perspective view of a conventional probe module;

FIG. 2 is a side view of the conventional probe module;

FIG. 3 is a perspective view of a first embodiment of the present invention;

FIG. 4 is a side view of the first embodiment of the present invention;

FIG. 5 is a partial sectional view of the electrical signal transmitting member of the first embodiment of the present invention;

FIG. 6 is a perspective view of the second embodiment of the present invention;

FIG. 7 is a side view of the second embodiment of the present invention;

FIG. 8 is a perspective view of a third embodiment of the present invention;

FIG. 9 is a side view of the third embodiment of the present invention;

FIG. 10 is a perspective view of a fourth embodiment of the present invention;

FIG. 11 is a perspective exploded view of the fourth embodiment seen from another perspective;

FIG. 12 is a partial top view of the fourth embodiment of the present invention;

FIG. 13 is a perspective view of a fifth embodiment of the present invention;

FIG. 14 is a side view of the fifth embodiment of the present invention;

FIG. 15 is a partial top view of the fifth embodiment of the present invention;

FIG. 16 is a perspective view of a sixth embodiment of the present invention;

FIG. 17 is a side view of the sixth embodiment of the present invention;

FIG. 18 is a perspective view of a seventh embodiment of the present invention;

FIG. 19 is a partial perspective exploded view of the seventh embodiment of the present invention;

FIG. 20 is a side view of the seventh embodiment of the present invention;

FIG. 21 is a perspective view of an eighth embodiment of the present invention;

FIG. 22 is a side view of the eighth embodiment of the present invention;

FIG. 23 is a perspective view of a ninth embodiment of the present invention;

FIG. 24 is a side view of the ninth embodiment of the present invention;

FIG. 25 is a perspective view of a tenth embodiment of the present invention;

FIG. 26 is a side view of the tenth embodiment of the present invention;

FIG. 27 is a perspective view of an eleventh embodiment of the present invention; and

FIG. 28 is a side view of the eleventh embodiment of the present invention.

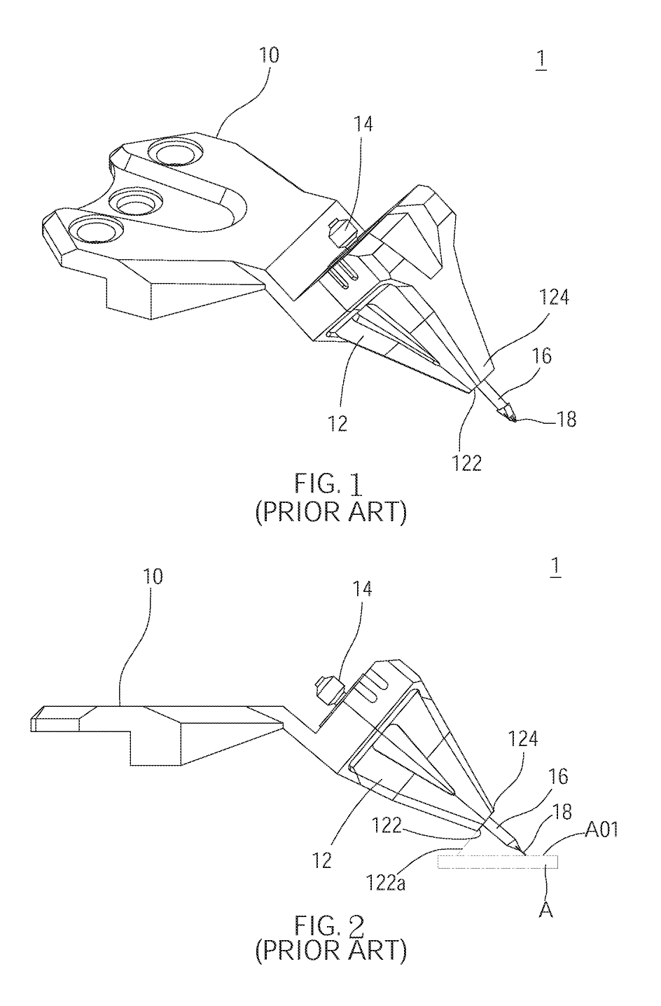

### DETAILED DESCRIPTION OF THE INVENTION

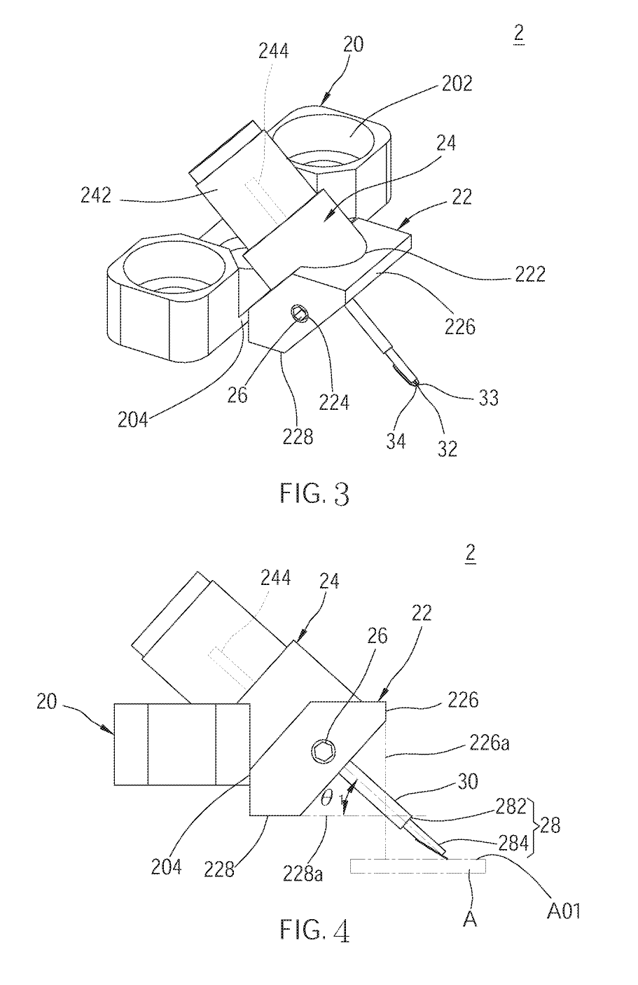

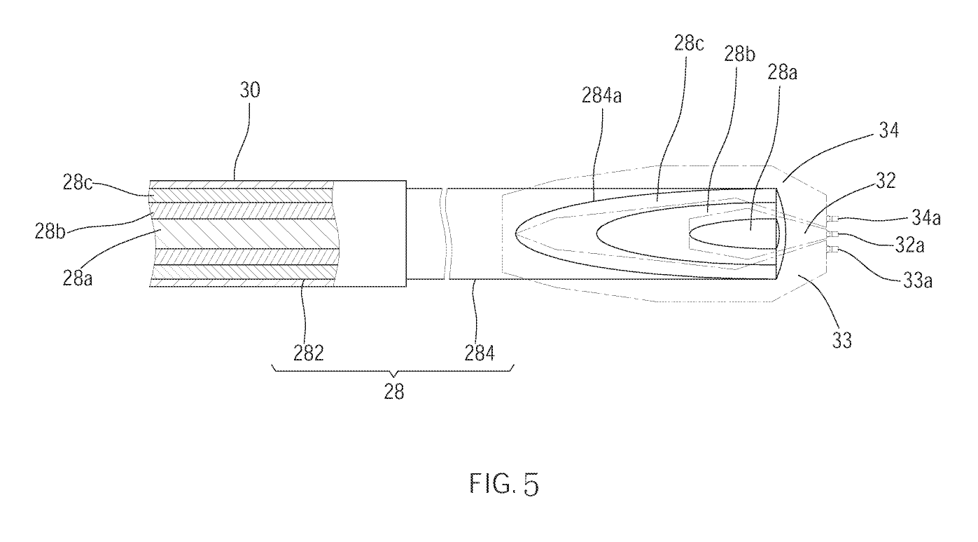

As shown in FIG. 3 and FIG. 5, a probe module 2 of the first embodiment of the present invention, which is provided between a tester (not shown) and a device-under-test (DUT), wherein the DUT A has a tested surface A01. The probe module 2 includes a base 20, an engaging seat 22, a signal connector 24, an electrical signal transmitting member 28, and three probes 32-34.

The base 20 has two fixing holes 202, which are adapted to be passed by two screws (not shown) to fix the base 20 on the tester.

The engaging seat 22 is engaged with a front surface 204 of the base 20, and leans outward from the front surface 204 of the base 20. The engaging seat 22 has an engaging opening 222 and a side threaded hole 224, wherein the engaging opening 222 goes through the engaging seat 22 in a tilted manner, with a bottom thereof farther away from the base 20 than a top thereof. The side threaded hole 224 communicates with the engaging opening 222. In addition, the engaging seat 22 has a first end surface 226 and a second end surface 228, wherein the first end surface 226 is on a side of the engaging seat 22 away from front surface 204 of the base 20, and the second end surface 228 is at a bottommost part of the engaging seat 22. A defined first extending reference plane 226a of the first end surface 226 is perpendicular to a defined second extending reference plane 228a of the second end surface 228. Furthermore, the first extending reference plane 226a is perpendicular to the tested surface A01 of the DUT A, and the second extending reference plane 228a is parallel to the tested surface A01 of the DUT A.

The signal connector 24 is provided on the engaging seat 22, and passes through the engaging opening 222, wherein the signal connector 24 is fixed therein by a set screw 26, which screws into the side threaded hole 224 and tightly abuts against an outer peripheral surface of the signal connector 24. The signal connector 24 has a conductive ground 242 and a signal conductive portion 244. In the first embodiment, the conductive ground 242 is a metal case, and the signal conductive portion 244 is a metal rod in the conductive ground 242 (i.e., the metal case). The signal conductive portion 244 and the conductive ground 242 are adapted to electrically connect a signal terminal (not shown) to the tester.

As shown in FIG. 5, the electrical signal transmitting member 28 is rod-shaped, including a signal wire 28a made of a conducting material, an insulating layer 28b made of an insulating material, and a ground layer 28c made of a conductive material, wherein the insulating layer 28b covers the signal wire 28a, while the ground layer 28c covers the insulating layer 28b. The electrical signal transmitting member 28 is defined to have a first segment 282 and a second segment 284, which are connected to each other, and are located below the engaging seat 22, wherein an end of the first segment 282 is located in the signal connector 24. The signal wire 28a and the ground layer 28c located in the first segment 282 are electrically connected to the signal conductive portion 244 and the conductive ground 242, respectively. The first segment 282 is fitted around by an absorbing sleeve 30, wherein a part of the first segment 282 and a part of the absorbing sleeve 30 are exposed underneath the engaging seat 22. The absorbing sleeve 30 is made of an absorbing material to absorb noises, preventing the noises from interfering with the transmission of electrical signals. In the first embodiment, a part of the first segment 282, a part of the absorbing sleeve 30, and the second segment 284 extend out of the first extending reference plane 226a. An end of the second segment 284 of the electrical signal transmitting member 28 has a cutting surface 284a, so that the signal wire 28a, the insulating layer 28b and the ground layer 28c are exposed. In the first embodiment, an included angle θ1 between a major axial direction of the electrical signal transmitting member 28 and the second extending reference plane 228a is 32-52 degrees.

The probes 32-34 are made of a conducting material, wherein each of the probes 32-34 has a tip 32a-34a at an end thereof, and the tips 32a-34a are adapted to contact with a tested portion on the tested surface A01 of the DUT A. A surface of each of the probes 32-34 is welded to the cutting surface 284a of the first segment 282, wherein one of the probes 32-34 (i.e., the probe 32) is electrically connected to the signal wire 28a, while the other two of the probes 32-34 (i.e., the probes 33, 34) are electrically connected to the ground layer 28c. Whereby, the whole piece of each of the probes 32-34 extends out of the first extending reference plane 226a directly under the engaging seat 22, and are located within an orthogonal projection of the engaging seat 22. Furthermore, each of the tips 32a-34a is lower than the second extending reference plane 228a. In practice, there could be only two probes to meet different requirements for the tested portion, wherein each of which is electrically connected to the signal wire and the ground layer, respectively.

With the aforementioned design, while using the probe module 2 to test the DUT A, the locations of the probes 32-34 could be observed with a microscope or naked eyes from above the probe module 2, whereby the probes 32-34 could be easily moved to above the tested portion of the DUT A for testing. It is worth mentioning that, since the first end surface 226 is perpendicular to the tested surface A01 of the DUT A, a length of the electrical signal transmitting member 28 could be further shortened in comparison to a conventional probe module, of which an electrical signal transmitting member may have unnecessary length at the portion directly below the front end angle of the engaging seat. Therefore, the electrical signal transmitting member 28 of the first embodiment of the present invention could omit a redundant length, and shorten the signal transmission path, which effectively reduces the signal loss caused by high-frequency signals, and makes the high-frequency signals more accurate.

In addition, since the second end surface 228 is parallel to the tested surface A01, the engaging seat 22 could be designed closer to the DUT A than that of a conventional probe module. As a result, the length of the electrical signal transmitting member 28 could be further shortened.

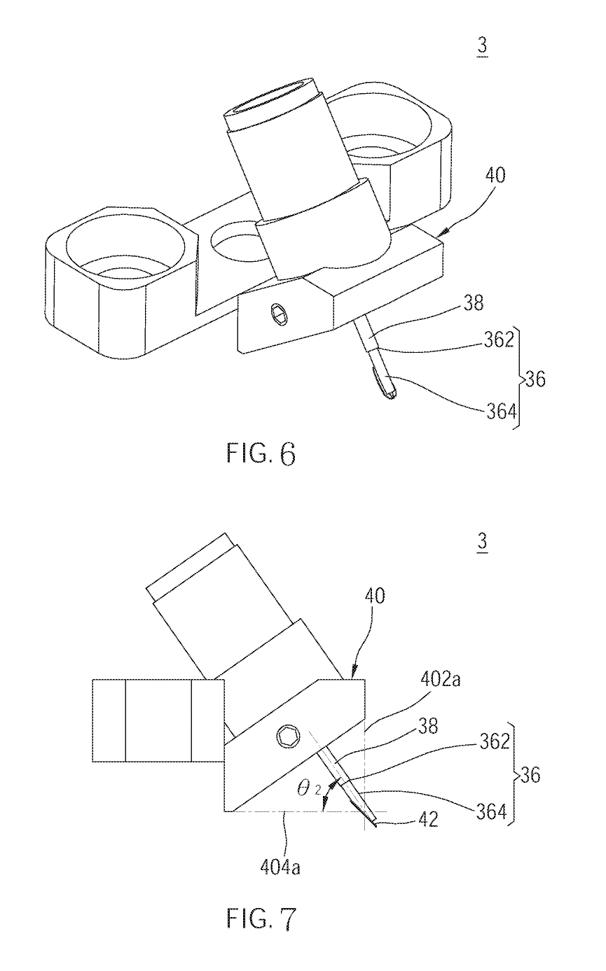

A probe module 3 of a second embodiment of the present invention is illustrated in FIG. 6 and FIG. 7, which has approximately the same structure as that of the aforementioned first embodiment, except that an included angle θ2 between a major axial direction of an electrical signal transmitting member 36 and a second extending reference plane 404a of the second embodiment is 45-65 degrees, and a first segment 362 of the electrical signal transmitting member 36 and an absorbing sleeve 38 are located within an orthogonal projection of an engaging seat 40. Furthermore, a part of a second segment 364 and a part of each of probes 42 are also located within the orthogonal projection of the engaging seat 40. In other words, for each of the probes 42, only a part thereof extends out of the first extending reference plane 402a. Whereby, a length of the electrical signal transmitting member 36 could be further shortened in comparison to the electrical signal transmitting member 28 of the first embodiment.

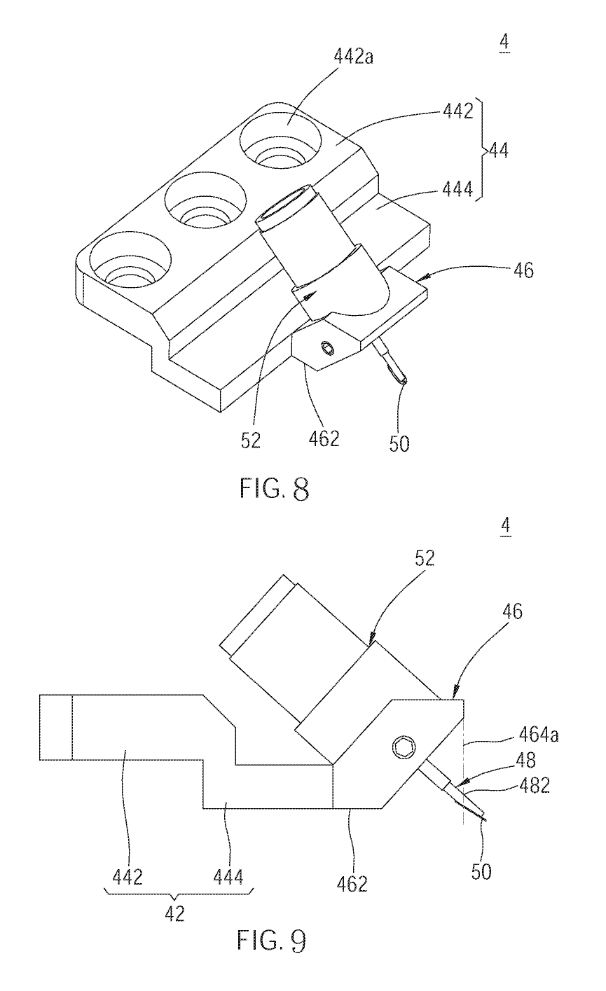

A probe module 4 of a third embodiment of the present invention is illustrated in FIG. 8 and FIG. 9, which has approximately the same structure as that of the aforementioned first embodiment, except that a base 44 of the third embodiment includes a first body 442 and a second body 444 which are connected together, wherein the first body 442 has a plurality of fixing holes 442a provided thereon to be fixed to the tester. In more details, the second body 444 is away from the first body 442 by a distance in a vertical direction, so that the second body 444 is lower than the first body 442. An engaging seat 46 of the third embodiment is engaged with the second body 444, and a second end surface 462 (i.e., the bottommost surface of the engaging seat 46) aligns with a bottommost end of the second body 444. A part of a second segment 482 of an electrical signal transmitting member 48 and a part of each of probes 50 are also located within an orthogonal projection of the engaging seat 46, with only a part of each of the probe 50 extending out of a first extending reference plane 464a. Since the second body 444 is lower than the first body 442, much space is available around a signal connector 52 to conveniently install a signal terminal of the tester to the signal connector 52.

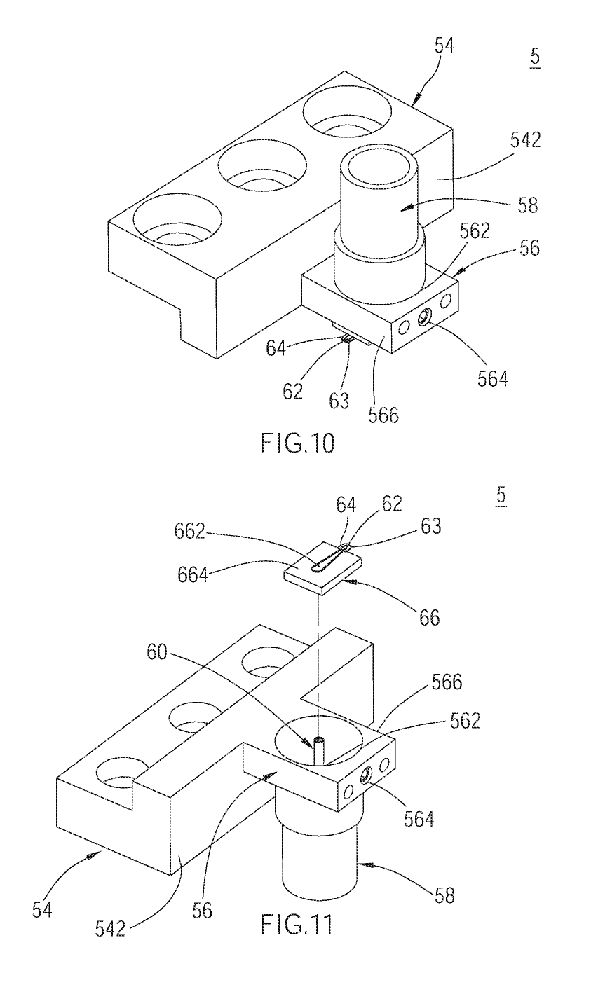

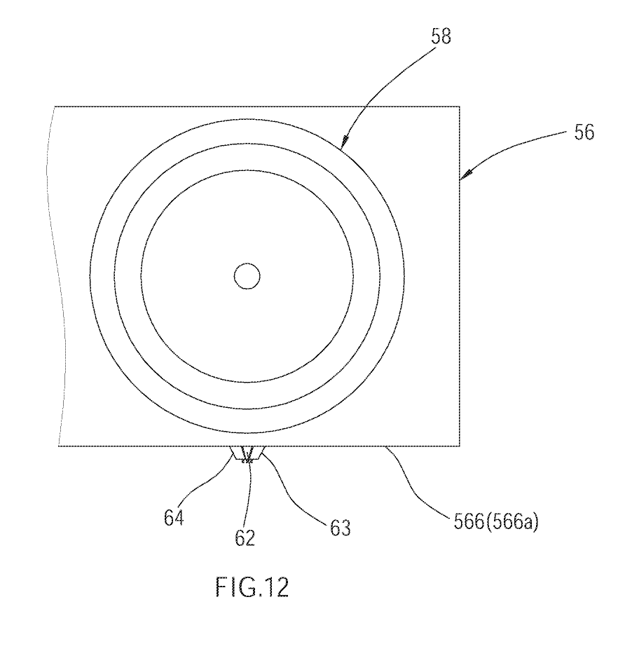

A probe module 5 of a fourth embodiment of the present invention is illustrated in FIG. 10, FIG. 11, and FIG. 12. Similar to the structure of the first embodiment, the probe module 5 of the fourth embodiment also includes a base 54, an engaging seat 56, a signal connector 58, an electrical signal transmitting member 60, and three probes 62-64. Differently, an engaging opening 562 of the engaging seat 56 of the fourth embodiment vertically goes through the engaging seat 56, and a side threaded hole 564 is provided on a side of the engaging seat 56 away from a front surface 542 of the base 54. A first end surface 566 of the engaging seat 56 is near the front surface 542 of the base 54. The electrical signal transmitting member 60 is vertically provided in the signal connector 58, and is within an orthogonal projection of the engaging seat 56. In addition, the probe module 5 further includes a printed circuit board 66, which is also within the orthogonal projection of the engaging seat 56. A bottom surface of the printed circuit board 66 has at least two conductive traces 662, 664 provided thereon through circuit layout, wherein one of the conductive traces 662, 664 (i.e., the conductive trace 662) is electrically connected to a signal wire of the electrical signal transmitting member 60, while the other one of the conductive traces 662, 664 (i.e., the conductive trace 664) is electrically connected to a ground layer of the electrical signal transmitting member 60. In practice, the electrical signal transmitting member 60 and the conductive traces 662, 664 could be electrically connected through conductive vias on the printed circuit board 66.

Each of the probes 62-64 is provided at an edge of the printed circuit board 66 which is near the first end surface 566, with a part of each of the probes 62-64 extending out of a first extending reference plane 566a of the first end surface 566. One of the probes 62-64 (i.e., the probe 62) is welded to one of the conductive traces 662, 664 (i.e., the conductive trace 662), and is electrically connected to the signal wire of the electrical signal transmitting member 60 through the conductive trace 662, while the other two of the probes 62-64 (i.e., the probes 63, 64) are welded to the other one of the conductive traces 662, 664 (the conductive trace 666), and are electrically connected to the ground layer of the electrical signal transmitting member 60 through the conductive trace 664.

With the aforementioned design, again, only a part of each of the probes 62-64 is exposed out of the first extending reference plane 566a, which also shortens a length of a signal transmission path thereof.

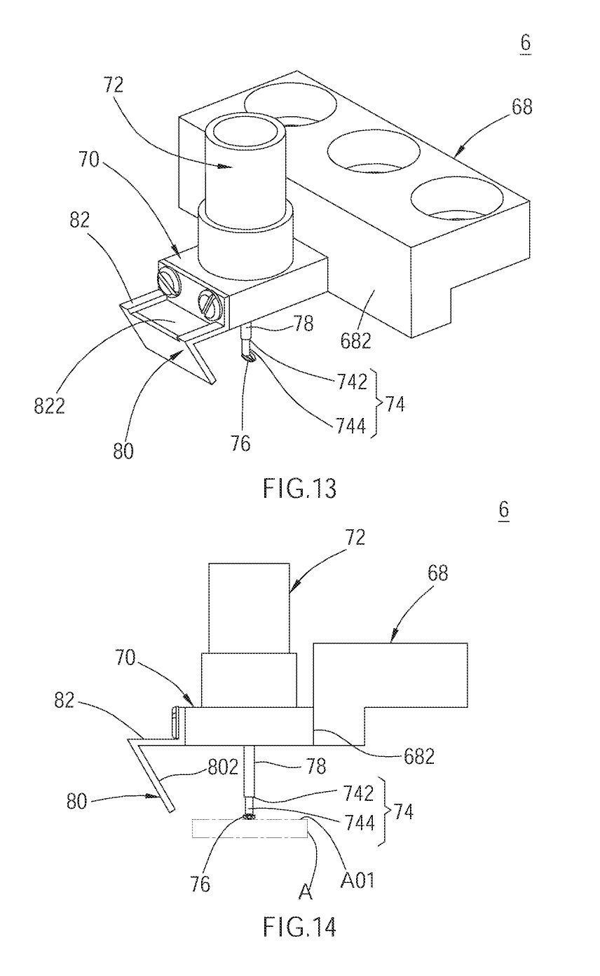

A probe module 6 of a fifth embodiment of the present invention is illustrated in FIG. 13 and FIG. 14. Similar to the structure of the fourth embodiment, the probe module 6 of the fifth embodiment also includes a base 68, an engaging seat 70, a signal connector 72, an electrical signal transmitting member 74, and two probes 76. Differently, the electrical signal transmitting member 74 has a first segment 742 and a second segment 744 which are connected together, wherein the first segment 742 is fitted around by an absorbing sleeve 78. An end of the first segment 742 is located in the signal connector 72, and a signal wire and a ground layer located in the first segment 742 are electrically connected to a signal conductive portion and a conductive ground of the signal connector, respectively. The first segment 742 extends downward, and a part of the first segment 742 and a part of the absorbing sleeve 78 are exposed below the engaging seat 70. A major axial direction of the electrical signal transmitting member 74 is perpendicular to the tested surface A01 of the DUT A. The probes 76 are under the engaging seat 70, and are within an orthogonal projection of the engaging seat 70. The probes 76 are electrically connected to the signal wire and the ground layer below the second segment 744 of the electrical signal transmitting member 74, respectively.

In addition, the probe module 6 further includes a reflector 80, which is provided on a side of the engaging seat 70 opposite to a front surface 682 of the base 68. In the fifth embodiment, the reflector 80 are provided on the engaging seat 70 through two connecting arms 82, wherein an end of each of the connecting arms 82 is fixedly connected to the engaging seat 70, while another end thereof is connected to the reflector 80. The connecting arms 82 are separated from each other by a distance to form an opening 822. The reflector 80 has a reflective surface 802 below the opening 822, wherein the reflective surface 802 is provided in a tilted manner and corresponding to the probes 76, whereby the reflective surface 802 could reflect an image of the probes 76 and the DUT A upward. A bottommost end of the reflector 80 is higher than the tips of the probes 76.

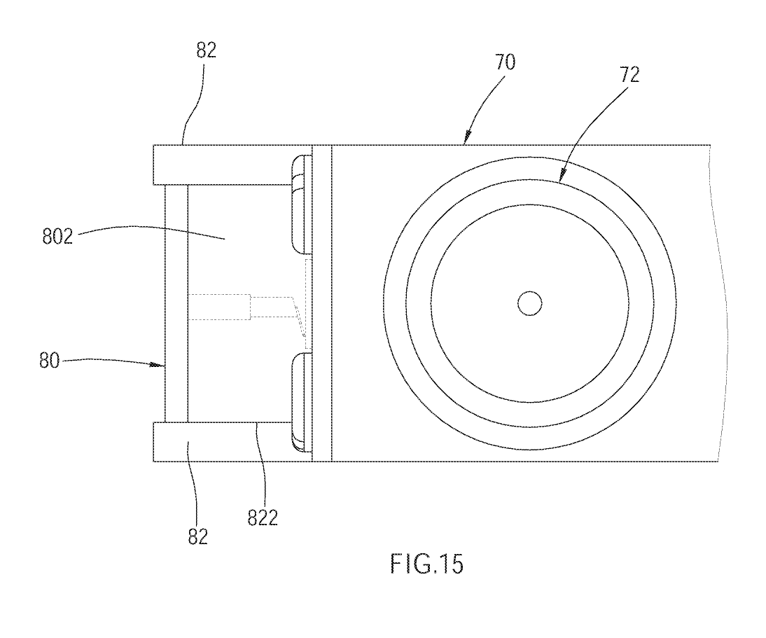

As shown in FIG. 15, by observing with a microscope or naked eyes from above the probe module 6, the locations of the probes 76 relative to the DUT A could be seen through the opening 822. It is worth mentioning that, since the electrical signal transmitting member 74 is perpendicular to the tested surface A01 of the DUT A, the electrical signal transmitting member 74 has a shortest signal transmission path, which effectively reduces a length of the signal transmission path between the tester and the DUT A.

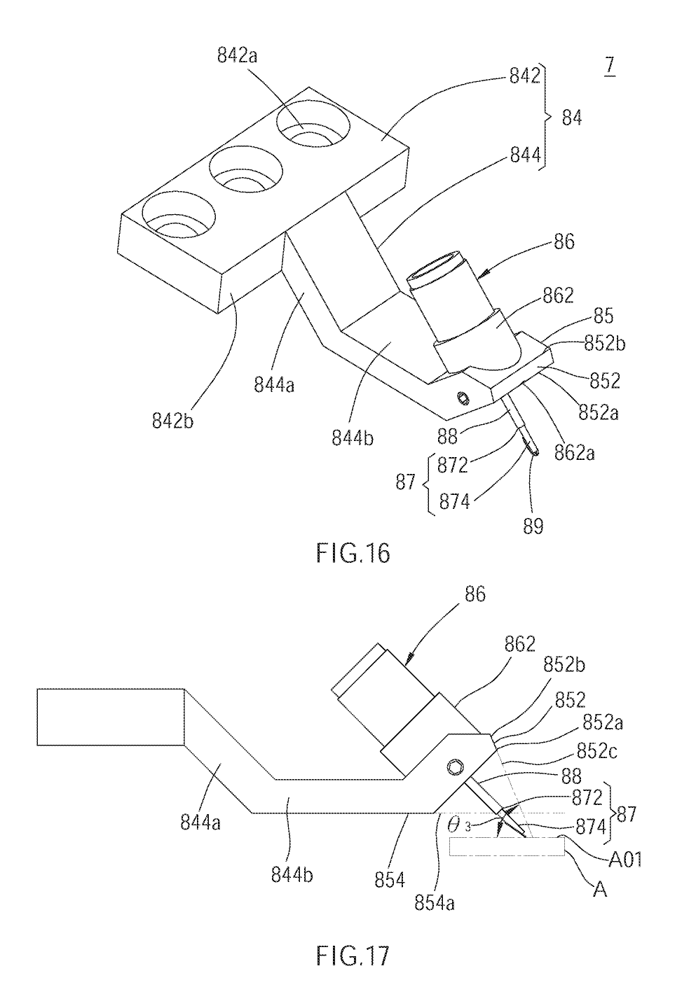

A probe module 7 of a sixth embodiment of the present invention is illustrated in FIG. 16 and FIG. 17, which has approximately the same structure as that of the aforementioned first embodiment, except that a base 84 of the sixth embodiment includes a first body 842 and a second body 844, wherein the first body 842 has a plurality of fixing holes 842a provided thereon to be fixed to the tester. A width of the second body 844 is less than a width of the first body 842. The second body 844 has a tapered segment 844a and a straight segment 844b, wherein the tapered segment 844a is tilted downward, with an upper end thereof connected to a front surface 842b of the first body 842, while an end of the straight segment 844b is connected to a lower end of the tapered segment 844a.

The engaging seat 85 of the sixth embodiment is integrally connected to another end of the straight segment 844b. In addition, the engaging seat 85 also has a first end surface 852 and a second end surface 854. Differently, the first end surface 852 is tilted toward the base from a bottom edge 852a thereof to a top edge 852b thereof. An included angle θ3 between a first extending reference plane 852c of the first end surface 852 and the tested surface A01 of the DUT A is less than 90 degrees. An end edge 862a of a conductive ground 862 of a signal connector 86 aligns with the bottom edge 852a of the first end surface 852. Similarly, the second end surface 854 is the bottommost surface of the engaging seat 85, and aligns with a lower end of the straight segment 844b of the second body 844. A second extending reference plane 854a of the second end surface 854 is also parallel to the tested surface A01 of the DUT A.

Similar to the first embodiment, an absorbing sleeve 88 and a second segment 874 of an electrical signal transmitting member 87 of the sixth embodiment also extend out of an orthogonal projection of the engaging seat 85. Whereby, the location of the probe 89 could be easily observed from above the probe module 7.

In practice, a first segment 872 of the electrical signal transmitting member 87 and the absorbing sleeve 88 could also located within the orthogonal projection of the engaging seat 85, with only a part of the second segment 874 and a part of the probe 89 located outside of the orthogonal projection of the engaging seat 85, as described in the second embodiment.

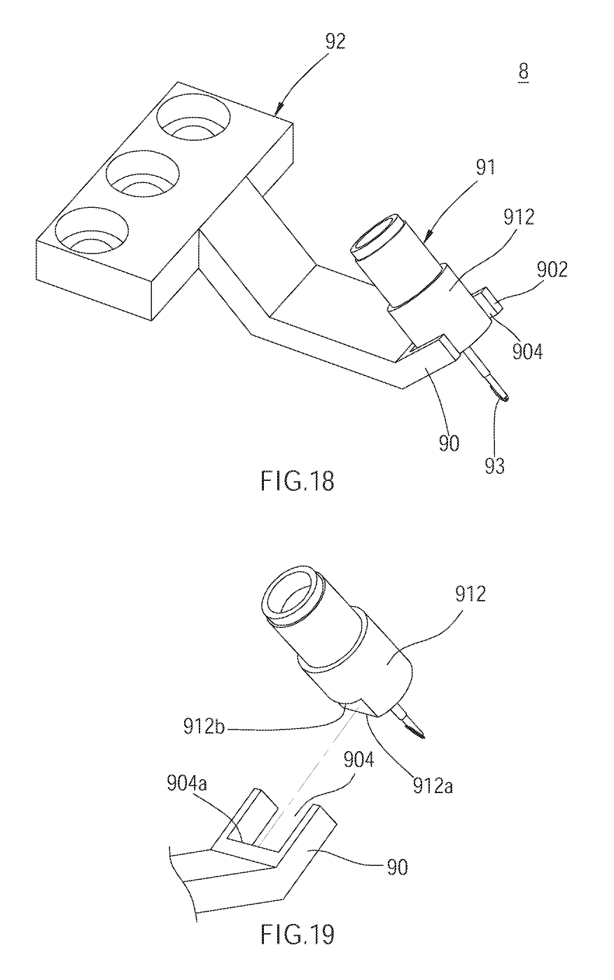

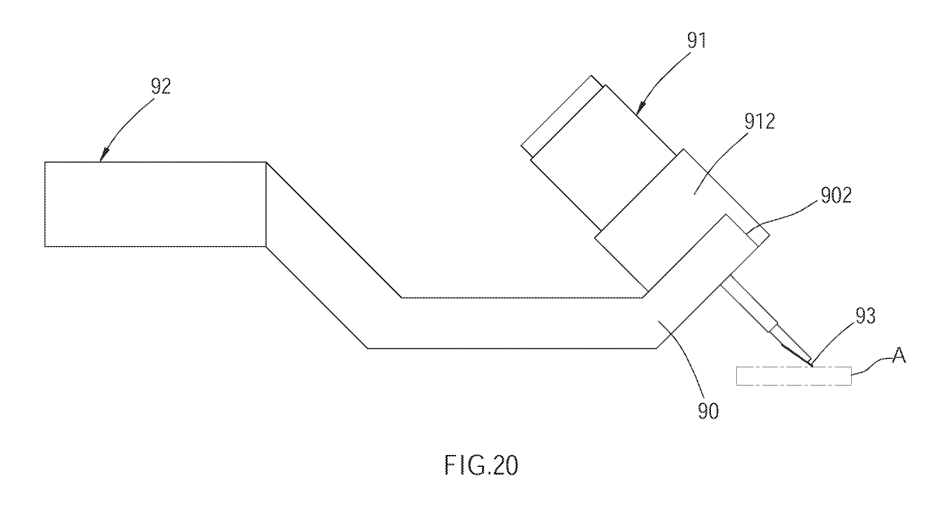

A probe module 8 of a seventh embodiment of the present invention is illustrated in FIG. 18 to FIG. 20, which has approximately the same structure as that of the aforementioned sixth embodiment, except that a first end surface 902 of an engaging seat 90 has a notch 904 formed thereon, and a conductive ground 912 of a signal connector 91 is provided in the engaging seat 90. More specifically, the conductive ground 912 is received in the notch 904. A part of the conductive ground 912 of the signal connector 91 extends out of the first end surface 902 from the notch 904. In other words, a side of the conductive ground 912 which is away from the base 92 is not covered by the engaging seat 90, and therefore is exposed. In addition, an outer peripheral surface of the conductive ground 912 of the signal connector 91 has a plane 912a and a shoulder 912b, wherein the plane 912a abuts against a wall 904a of the notch 904, while the shoulder 912b abuts against a periphery of the notch 904. In this way, the location of the signal connector 91 could be fixed. Whereby, the locations of a probe 93 could also be easily observed from above the probe module 8.

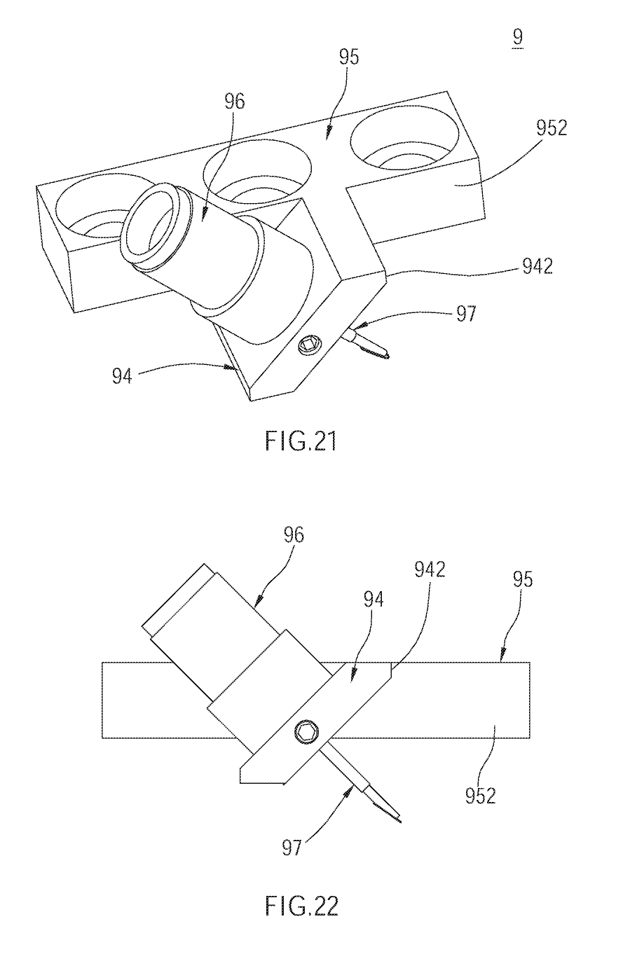

A probe module 9 of an eighth embodiment of the present invention is illustrated in FIG. 21 and FIG. 22, which has approximately the same structure as that of the aforementioned second embodiment, except that, in the eighth embodiment, a first end surface 942 of an engaging seat 94 is adjacent to a front surface 952 of a base 95, and is substantially perpendicular to the front surface 952. An axial direction of a signal connector 96 and a major axial direction of the electrical signal transmitting member 97 are substantially parallel to the front surface 952.

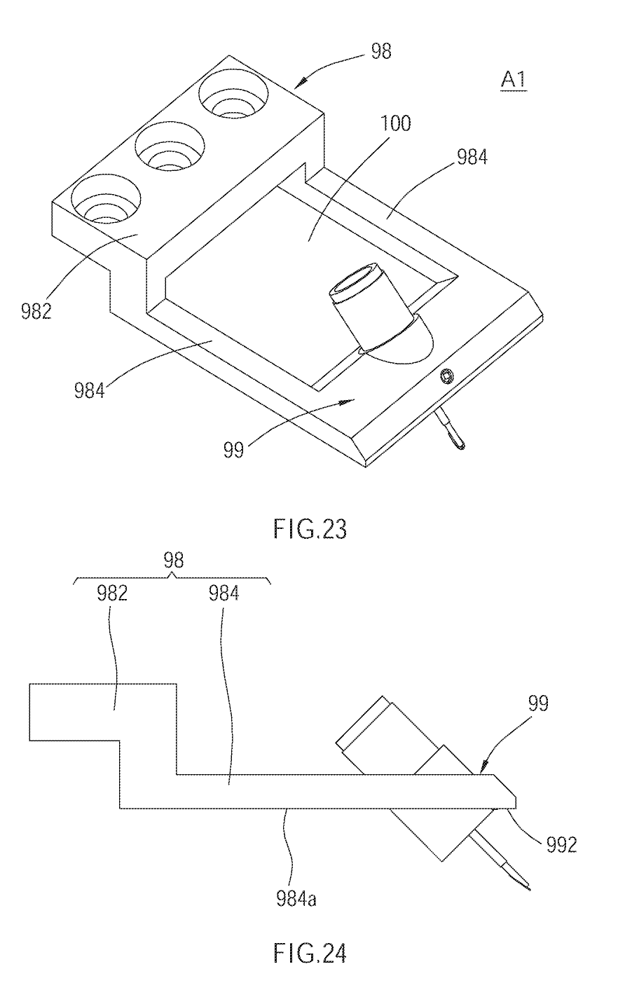

A probe module A1 of a ninth embodiment of the present invention is illustrated in FIG. 23 and FIG. 24, which has approximately the same structure as that of the aforementioned third embodiment, except that a base 98 in the ninth embodiment includes a main body 982 and two extending arms 984, wherein the extending arms 984 are away from the main body 982 by a distance in a vertical direction, so that the extending arms 984 are lower than the main body 982. The extending arms 984 are separated from each other by a distance, wherein an end of each of the extending arms 984 is connected to the main body 982, while another end thereof is connected to an engaging seat 99. A hollow portion 100 is formed between the main body 982, the extending arms 984m and the engaging seat 99. A bottom end 984a of each of the extending arms 984 aligns with a second end surface 992 of the engaging seat 99.

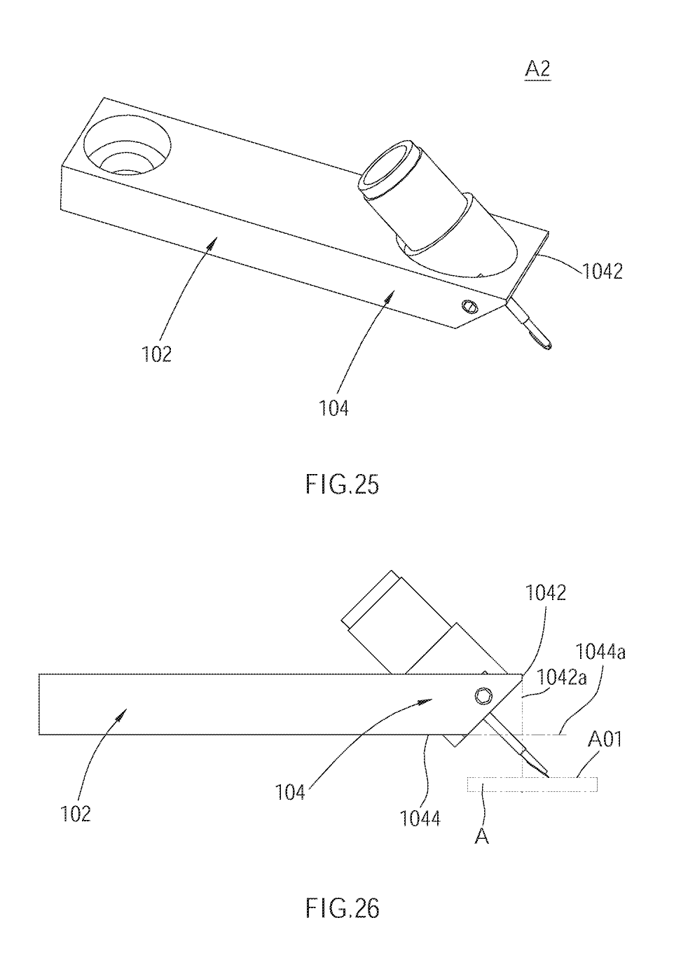

A probe module A2 of a tenth embodiment of the present invention is illustrated in FIG. 25 and FIG. 26, which has approximately the same structure as that of the aforementioned first embodiment, except that a base 102 and an engaging seat 104 of the tenth embodiment are integrally made, wherein the base 102 and the engaging seat 104 have identical widths and identical thicknesses. Again, a first extending reference plane 1042a of a first end surface 1042 of the engaging seat 104 is substantially perpendicular to the tested surface A01 of the DUT A. At the same time, a second extending reference plane 1044a of a second end surface 1044 of the engaging seat 104 is also parallel to the tested surface A01 of the DUT A. In practice, an included angle between the first extending reference plane of the first end surface and the tested surface A01 of the DUT A could be less than 90 degrees, as described in the sixth embodiment.

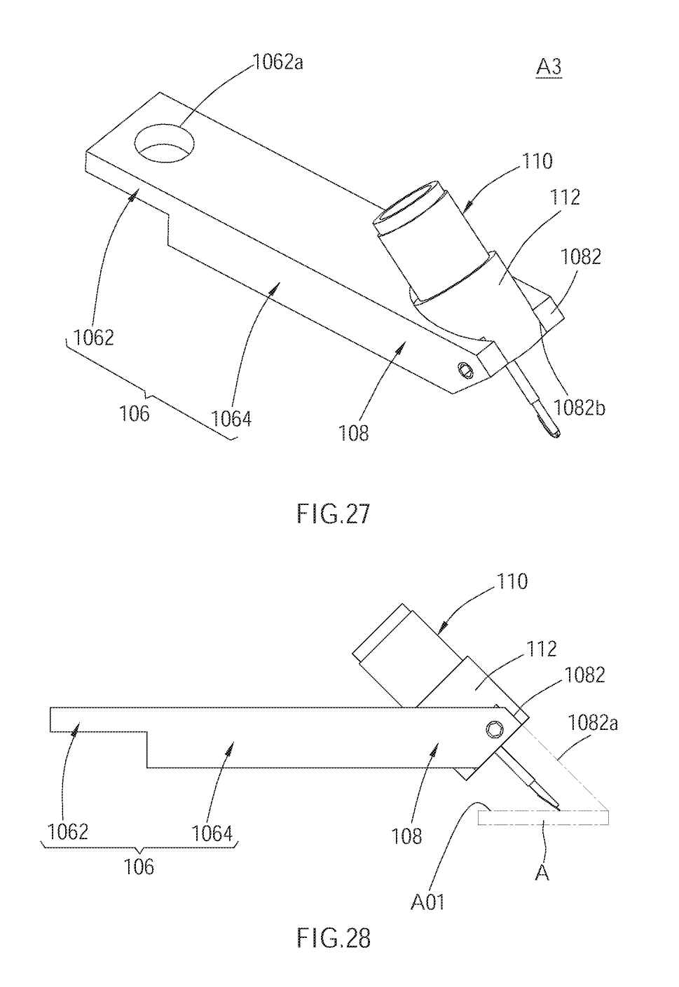

A probe module A3 of an eleventh embodiment of the present invention is illustrated in FIG. 27 and FIG. 28, which has approximately the same structure as that of the aforementioned tenth embodiment, except that a base 106 of the eleventh embodiment includes a first body 1062 and a second body 1064 which are connected together, wherein the first body 1062 has a fixing hole 1062a, and a width of the second body 1064 equals a width of the first body 1062, while a thickness of the second body 1064 is greater than a thickness of the first body 1062. An engaging seat 108 is connected to the second body 1064, and these two components have the same widths and the same thickness. In addition, an included angle between a first extending reference plane 1082a of a first end surface 1082 of the engaging seat 108 and the tested surface A01 of the DUT A is less than 90 degrees. The first end surface 1082 has a notch 1082b formed thereon, and a conductive ground 112 of a signal connector 110 is provided in the engaging seat 108. More specifically, the conductive ground 112 is located in the notch 1082b.

In summary, since the first end surface of the engaging seat is delicately designed to be perpendicular to the tested surface of the DUT, a length of the electrical signal transmitting member could be shortened as much as possible, whereby a length of the signal transmission path would be shortened as well. As a result, the signal loss of high-frequency signals could be effectively reduced, which improves the accuracy of high-frequency tests. In comparison, the electrical signal transmitting member of a conventional probe module is shaded by the front end angle of the engaging seat, and therefore a length of the electrical signal transmitting member is unavoidable long, as mentioned above. Such drawback could be overcome with the design disclosed in the present invention. In addition, as described in the fifth to the seventh embodiments, by providing the reflector next to the engaging seat to reflect an image of the probes, by arranging the first end surface of the engaging seat in a tilted manner which leans toward the base from bottom to top, and by placing the engaging seat in the notch, the aforementioned drawback could be also avoided, which further shortens the length of the electrical signal transmitting member.

It must be pointed out that the embodiments described above are only some embodiments of the present invention. All equivalent structures which employ the concepts disclosed in this specification and the appended claims should fall within the scope of the present invention.

What is claimed is:

1. A probe module, which is provided between a tester and a device-under-test (DUT) to abut against a tested surface of the DUT; comprising:
a base adapted to be fixed to the tester;
an engaging seat engaged with the base, wherein the engaging seat has an engaging opening and a first end surface; the engaging opening goes through the engaging seat; a defined first extending reference plane of the first end surface is perpendicular to the tested surface of the DUT;
a signal connector provided at the engaging seat and in the engaging opening, wherein the signal connector is adapted to be electrically connected to the tester; the signal connector has a signal conductive portion and a conductive ground;
an electrical signal transmitting member, which is rod-shaped, comprising a signal wire made of a conducting material, an insulating layer made of an insulating material, and a ground layer made of a conducting material, wherein the insulating layer covers the signal wire, and the ground layer covers the insulating layer; the signal wire is electrically connected to the signal conductive portion, and the ground layer is electrically connected to the conductive ground; and
at least two probes made of a conducting material, which are adapted to abut against the tested surface of the DUT, wherein the at least two probes are electrically connected to the signal wire and the ground layer at an end of the electrical signal transmitting member, respectively; at least a part of each of the at least two probes extends out of the first extending reference plane from directly below the engaging seat.

2. The probe module of claim 1, further comprising an absorbing sleeve made of an absorbing material, wherein the electrical signal transmitting member comprises a first segment and a second segment, which are connected together, and located below the engaging seat; the absorbing sleeve fits around the first segment, with a part of the absorbing sleeve exposed out of the engaging seat; the at least two probes are engaged with the second segment at an end of the second segment.

3. The probe module of claim 2, wherein a part of the first segment of the electrical signal transmitting member and the second segment extend out of the first extending reference plane from directly below the engaging seat, so that each of the at least two probes completely extends out of the first extending reference plane.

4. The probe module of claim 2, wherein the first segment and the absorbing sleeve are located within an orthogonal projection of the engaging seat.

5. The probe module of claim 4, wherein each of the at least two probes has merely a part thereof extending out of the first extending reference plane.

6. The probe module of claim 1, wherein the engaging seat has a second end surface, which is a bottommost surface of the engaging seat; a defined second extending reference plane of the second end surface is parallel to the tested surface of the DUT;
each of the at least two probes has a tip, which is located lower than the second extending reference plane.

7. The probe module of claim 6, wherein the base comprises a first body and a second body which are connected together; the first body is adapted to be fixed to the tester; the second body is engaged with the engaging seat, wherein the second body is lower than the first body, and a bottom end of the second body aligns with the second end surface of the engaging seat.

8. The probe module of claim 6, wherein the base comprises a main body and two extending arms connected to the main body; the extending arms are separated from each other by a distance; an end of each of the extending arms is connected to the main body, while another end thereof is connected to the engaging seat; a hollow portion is formed between the main body, the extending arms, and the engaging seat; a bottom end of each of the extending arms aligns with the second end surface of the engaging seat.

9. The probe module of claim 1, further comprising a printed circuit board, which has at least two conductive traces laid out thereon; the printed circuit board and the electrical signal transmitting member are located within an orthogonal projection of the engaging seat; the at least two probes are welded to the conductive traces, respectively;
the at least two probes are electrically connected to the signal wire and the ground layer of the electrical signal transmitting member through the conductive traces, respectively.

10. A probe module, which is provided between a tester and a device-under-test (DUT) to abut against a tested surface of the DUT; comprising:
a base adapted to be fixed to the tester;
an engaging seat engaged with the base, wherein the engaging seat has an engaging opening going through the engaging seat;
a signal connector provided at the engaging seat and in the engaging opening, wherein the signal connector is adapted to be electrically connected to the tester; the signal connector has a signal conductive portion and a conductive ground;
an electrical signal transmitting member, which is rod-shaped, and is located within an orthogonal projection of the engaging seat, wherein the electrical signal transmitting member comprises a signal wire made of a conducting material, an insulating layer made of an insulating material, and a ground layer made of a conducting material, wherein the insulating layer covers the signal wire, and the ground layer covers the insulating layer; the signal wire is electrically connected to the signal conductive portion, and the ground layer is electrically connected to the conductive ground;
at least two probes made of a conducting material, which are adapted to abut against the tested surface of the DUT, wherein the at least two probes are electrically connected to the signal wire and the ground layer at an end of the electrical signal transmitting member, respectively; the at least two probes are located below the engaging seat, and are within the orthogonal projection of the engaging seat; and
a reflector provided on a side of the engaging seat, wherein the reflector has a reflective surface which is provided in a tilted manner, and corresponds to the at least two probes; the reflective surface is adapted to reflect an image of the at least two probes upward.

11. The probe module of claim 10, further comprising two connecting arms, wherein an end of each of the connecting arms is connected to the engaging seat, while another end thereof is connected to the reflector; an opening is formed between the connecting arms, and the reflective surface is located below the opening.

12. The probe module of claim 11, wherein a bottommost end of the reflector is higher than a tip of each of the probes.

13. The probe module of claim 10, wherein a major axial direction of the electrical signal transmitting member is perpendicular to the tested surface.

14. The probe module of claim 10, further comprising an absorbing sleeve made of an absorbing material, wherein the electrical signal transmitting member comprises a first segment and a second segment, which are connected together, and located below the engaging seat; the absorbing sleeve fits around the first segment, with a part of the absorbing sleeve exposed out of the engaging seat; the at least two probes are engaged with the second segment at an end of the second segment.

15. A probe module, which is provided between a tester and a device-under-test (DUT) to abut against a tested surface of the DUT; comprising:
a base adapted to be fixed to the tester;
an engaging seat engaged with the base, wherein the engaging seat has a first end surface;
a signal connector provided at the engaging seat, wherein the signal connector is adapted to be electrically connected to the tester, and has a signal conductive portion and a conductive ground;
an electrical signal transmitting member, which is rod-shaped, comprising a signal wire made of a conducting material, an insulating layer made of an insulating material, and a ground layer made of a conducting material, wherein the insulating layer covers the signal wire, and the ground layer covers the insulating layer; the signal wire is electrically connected to the signal conductive portion, and the ground layer is electrically connected to the conductive ground; and
at least two probes made of a conducting material, which are connected to the electrical signal transmitting member, and are adapted to abut against the tested surface of the DUT, wherein the at least two probes are electrically connected to the signal wire and the ground layer at an end of the electrical signal transmitting member, respectively;
at least a part of each of the at least two probes extends out of an orthogonal projection of the engaging seat from directly below the engaging seat.

16. The probe module of claim 15, wherein the engaging seat has an engaging opening, which goes through the engaging seat; the first end surface of the engaging seat tilts toward the base from bottom to top; the signal connector is provided in the engaging opening, wherein the conductive ground of the signal connector has an end edge, which aligns with a bottom edge of the first end surface.

17. The probe module of claim 15, wherein the first end surface of the engaging seat has a notch formed thereon; the conductive ground of the signal connector is provided in the notch.

18. The probe module of claim 17, wherein a part of the conductive ground of the signal connector extends out of the first end surface from the notch.

19. The probe module of claim 17, wherein the conductive ground of the signal connector has a plane and a shoulder; the plane abuts against a wall of the notch, while the shoulder abuts against a periphery of the notch.

20. The probe module of claim 15, further comprising an absorbing sleeve made of an absorbing material, wherein the electrical signal transmitting member comprises a first segment and a second segment, which are connected together, and located below the engaging seat; the absorbing sleeve fits around the first segment, with a part of the absorbing sleeve exposed out of the engaging seat; the at least two probes are engaged with the second segment at an end of the second segment.

21. The probe module of claim 20, wherein a part of the first segment of the electrical signal transmitting member and the second segment extend out of the orthogonal projection of the engaging seat from directly below the engaging seat, so that each of the at least two probes completely extends out of the orthogonal projection of the engaging seat.

22. The probe module of claim 20, wherein the first segment and the absorbing sleeve are located within the orthogonal projection of the engaging seat.

23. The probe module of claim 22, wherein each of the at least two probes has merely a part thereof extending out of the orthogonal projection of the engaging seat.

24. The probe module of claim 15, wherein the engaging seat has a bottommost end surface, of which a defined extending reference plane is parallel to the tested surface of the DUT; each of the at least two probes has a tip, which is located lower than the extending reference plane.

25. The probe module of claim 24, wherein the base comprises a first body and a second body which are connected together; the first body is adapted to be fixed to the tester; the second body is engaged with the engaging seat, wherein the second body is lower than the first body, and a bottom end of the second body aligns with the bottommost end surface of the engaging seat.
